(19) United States
(12) Patent Application Publication
(10) Pub. No.: US 2023/0178390 A1
(43) Pub. Date: Jun. 8, 2023

(54) METHOD FOR ETCHING SILICON WAFER

(71) Applicant: SHIN-ETSU HANDOTAI CO., LTD., Tokyo (JP)

(72) Inventor: Kuniaki OONISHI, Nishigo-mura (JP)

(73) Assignee: SHIN-ETSU HANDOTAI CO., LTD., Tokyo (JP)

(21) Appl. No.: 17/924,248

(22) PCT Filed: Mar. 2, 2021
(86) PCT No.: PCT/JP2021/007801

§ 371 Date: Nov. 9, 2022

(30) Foreign Application Priority Data
May 27, 2020 (JP) 2020-092152

(51) Int. Cl. H01L 21/67; H01L 21/306

(52) U.S. Cl. CPC H01L 21/6708; H01L 21/30604

(57) ABSTRACT

A method for etching a silicon wafer, the method including a spin etching step in which while an acid etching solution is supplied to a front or back side surface of a silicon wafer through a supply nozzle, the silicon wafer is rotated to expand a supply range of the acid etching solution to perform acid etching throughout the front or back side surface of the silicon wafer. Before the rotation of the silicon wafer is started, an acid mixture containing at least hydrofluoric acid and nitric acid is added dropwise within an impinging jet area which is located immediately below the supply nozzle, and in which the acid etching solution supplied through the supply nozzle impinges on the surface of the silicon wafer. After the impinging jet area is covered with the acid mixture, the rotation of the silicon wafer is started to perform the spin etching step.

### TECHNICAL FIELD

The present invention relates to a method for etching a silicon wafer by spin etching.

### BACKGROUND ART

In the manufacturing process of a silicon wafer, a wafer thinly sliced from a single crystal ingot is generally flattened after chamfering and grinding processes. In this event, to the front side and back side surfaces of the wafer, various sizes of scratches and processing damages are introduced by these processes. When exposed in the subsequent steps, these can cause serious quality problems.

Hence, etching treatment is normally performed to remove such scratches and processing damages. Known types of this etching method include: batch processing, by which the front side and back side surfaces of multiple wafers are simultaneously treated; and spin etching processing, by which the front side surface and the back side surface of a wafer are sequentially treated in a single-wafer-processing approach (see Patent Document 1). Moreover, in accordance with purposes, there are two means: treating with an acid etching solution; and treating with an alkali etching solution. For example, in the case of acid etching, an acid mixture containing hydrofluoric acid, nitric acid, and the like whose concentrations are appropriately adjusted is generally used.

Patent Document 2 describes a method for etching a semiconductor wafer which can simultaneously accomplish uniform etching for thin wafer formation and uniform roughening as desired. In the method, after an etching solution mainly containing hydrofluoric acid and nitric acid is supplied on a horizontally-held silicon wafer to cover the entire upper surface, supplying the etching solution is stopped, and the silicon wafer is left alone, so that the etching reaction takes place.

### CITATION LIST

### Patent Literature

Patent Document 1: JP 2007-53178 A

Patent Document 2: JP 2001-93876 A

### SUMMARY OF INVENTION

### Technical Problem

The following problems have been found. When a silicon wafer is etched with an acid by conventional spin-etching processing, the etching speed is slow in an area where an acid etching solution supplied from a supply nozzle impinges on a front side surface of the silicon wafer immediately below the supply nozzle (hereinafter, referred to as “impinging jet area”). This degrades PV (Peak to Valley) in etching margin of the entire wafer. As a result, TTV (Total Thickness Variation) in a wafer plane after the etching is degraded. Such problems are more noticeable in a case of polished wafer (hereinafter, may also be referred to as “PW”) and the like whose wafer top layers hardly have processing residual stress (i.e., damage in the vicinity of the silicon front side surface) than ground surfaces with many processing residual stresses, and the like. Additionally, the larger the number of silicon wafers treated with an acid etching solution (the longer the life), the more noticeable the problems appear.

The present invention has been made to solve the above problems. An object of the present invention is to provide a method for etching a silicon wafer by spin etching processing which makes it possible to increase the etching speed in an impinging jet area, and suppress PV degradation on the etching margin and TTV degradation in a wafer plane after the etching.

### Solution to Problem

The present invention has been made to achieve the object and provides a method for etching a silicon wafer, comprising a spin etching step in which while an acid etching solution is being supplied to a front side surface or back side surface of a silicon wafer through a supply nozzle, the silicon wafer is rotated to expand a supply range of the acid etching solution to perform acid etching throughout the front side surface or back side surface of the silicon wafer, wherein

before the rotation of the silicon wafer is started, an acid mixture containing at least hydrofluoric acid and nitric acid is added dropwise within an impinging jet area which is located immediately below the supply nozzle, and in which the acid etching solution supplied through the supply nozzle impinges on the surface of the silicon wafer, and

after the impinging jet area is covered with the acid mixture, the rotation of the silicon wafer is started to perform the spin etching step.

Such a method for etching a silicon wafer makes it possible to increase the etching speed in the impinging jet area, and thereby suppress degradation of PV on the etching margin. Consequently, degradation of TTV in the wafer plane after the etching can be suppressed.

In this event, the impinging jet area can be a circular region having a diameter 0.8 times or more and 1.6 times or less as large as an inner diameter of the supply nozzle.

Covering such an impinging jet area with the acid mixture can more effectively increase the etching speed in the impinging jet area.

In this event, before the rotation of the silicon wafer is started, the acid mixture can be added dropwise in a liquid amount of 20 to 50 mL.

Thereby, only the impinging jet area can be more reliably covered with the acid mixture, and the etching speed in the impinging jet area can be increased more effectively.

In this event, within a period of 1 second or more and 2 seconds or less after the acid mixture is added dropwise within the impinging jet area, the rotation of the silicon wafer may be started to perform the acid etching.

Thereby, nitrite ions contributing to oxidation process can be generated in a more sufficient amount. Moreover, it is not necessary to concern about surface roughness. Consequently, the etching speed in the impinging jet area can be increased more effectively.

In this event, the acid etching solution to be used in the method for etching a silicon wafer can be a mixture solution containing hydrofluoric acid and nitric acid, or the mixture solution further containing any one or more of acetic acid, phosphoric acid, and sulfuric acid.

In this manner, more efficient acid etching is possible, and the etching speed in the impinging jet area can be further increased. Moreover, when such an acid etching solution is used, the acid etching solution can also be used as the acid mixture. This is suitable because the etching apparatus can be simplified.

### Advantageous Effects of Invention

As described above, the inventive method for etching a silicon wafer makes it possible to increase the overall etching speed in the impinging jet area immediately below the nozzle, and improve TTV value in the wafer plane after the etching.

### BRIEF DESCRIPTION OF DRAWINGS

FIG. 1 shows a schematic view of an etching apparatus usable in an etching method according to the present invention.

FIG. 2 shows a relation between TTV after etching and the amount of Si dissolved in an acid etching solution according to Example.

FIG. 3 shows a relation between TTV after etching and the amount of Si dissolved in an acid etching solution according to Comparative Example.

### DESCRIPTION OF EMBODIMENTS

Hereinafter, the present invention will be described in detail. However, the present invention is not limited thereto.

As noted above, there have been demands for a method for etching a silicon wafer in such a manner as to: increase the etching speed in an impinging jet area when a silicon wafer is etched by spin etching processing; and suppress PV degradation on the etching margin and TTV degradation in a wafer plane after the etching.

The present inventor and colleagues have earnestly studied the above problems and consequently found a method for etching a silicon wafer, the method including a spin etching step in which while an acid etching solution is being supplied to a front side surface or back side surface of a silicon wafer through a supply nozzle, the silicon wafer is rotated to expand a supply range of the acid etching solution to perform acid etching throughout the front side surface or back side surface of the silicon wafer. In this method, before the rotation of the silicon wafer is started, an acid mixture containing at least hydrofluoric acid and nitric acid is added dropwise within an impinging jet area which is located immediately below the supply nozzle, and in which the acid etching solution supplied through the supply nozzle impinges on the surface of the silicon wafer. After the impinging jet area is covered with the acid mixture, the rotation of the silicon wafer is started to perform the spin etching step. This method for etching a silicon wafer can increase the etching speed in the impinging jet area. As a result, PV degradation on the etching margin and TTV degradation in a wafer plane after the etching can be suppressed. This finding has led to the completion of the present invention.

The present inventor has found that when a silicon wafer is etched by adopting spin etching processing, the etching speed on the impinging jet area of the wafer tends to be slow, and that this degrades PV in the etching margin and degrades TTV in the wafer plane after the etching. Such problems are presumably caused by a synergy effect of: low surface potential energy contributing to reaction energy consumed by acid etching in the spin etching; and low flow rate of the etching solution in the diameter direction immediately below the nozzle.

Thus, the present inventor has focused on the fact that when a silicon wafer is etched with an acid, the more the nitrite ions contributing to the oxidation process, the faster the etching speed. The inventor has found that if nitrite ions are generated at a particular position on a wafer surface in advance and an acid etching solution is supplied thereto, an increase in the etching speed can be expected at the particular position, and that nitrite ions generated autocatalytically from nitrogen oxide can be utilized most conveniently and efficiently. Note that such phenomena are more noticeable when an acid mixture containing a hydrofluoric acid at a certain concentration or higher is used as the acid etching solution.

The present inventor has found that in a case where a silicon wafer is rotated to perform acid etching while an acid etching solution is being supplied to a front side surface or back side surface of the silicon wafer, if an acid mixture containing at least hydrofluoric acid and nitric acid is added dropwise to the impinging jet area located immediately below the nozzle to cover the impinging jet area with the acid mixture immediately before the acid etching is started, i.e., before the silicon wafer is rotated, an etching reaction between the acid mixture and the silicon wafer generates nitrogen oxide and nitrite ions therefrom. Thereafter, the etching speed in the impinging jet area immediately below the nozzle is increased if an etching solution is continuously supplied from the nozzle in synchronization with spin rotation initiation. These findings have led to the completion of the present invention.

Hereinbelow, an embodiment of a method for etching a silicon wafer according to the present invention will be described with reference to the drawing.

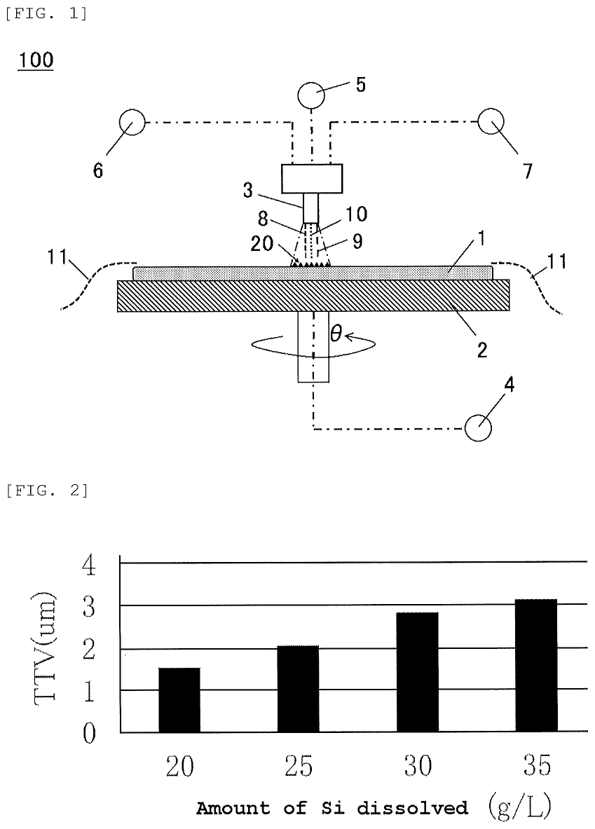

The inventive method for etching a silicon wafer can employ etching apparatuses that are used in general spin etching processing. FIG. 1 shows a schematic view of an etching apparatus usable in the inventive etching method. Specifically, a spin etcher MSE-7000EL-MH available from Mimasu Semiconductor Industry Co., Ltd can be used.

Generally, an etching apparatus 100 can include a vacuum sucking stage 2 and a supply nozzle 3 in a treatment section, where an etching treatment is performed. Further, the etching apparatus 100 can include an acid mixture tank 5, an acid-etching-solution tank 6, and a water supply source 7 in a chemical-solution supply section, from which an etching solution, water, etc. are supplied; and unillustrated liquid-supply pumps with which an acid mixture 10, an acid etching solution 8, and water 9 are sent to the treatment section from the acid mixture tank 5, the etching-solution tank 6, and the water supply source 7. Here, the acid mixture 10 contains at least hydrofluoric acid and nitric acid. Moreover, in the acid etching solution 8, silicon is normally dissolved. This is so structured because in acid etching of a silicon wafer by spin etching processing, the used acid etching solution is collected and used again as an acid etching solution, and because the amount of Si dissolved and contained in the acid etching solution is increased according to the number of silicon wafers etched. Note that, as will be described later, the acid mixture 10 and the acid etching solution 8 can be the same chemical solution. In such a case, the acid mixture tank 5 does not have to be provided.

A silicon wafer 1 can be horizontally set at the center of the vacuum sucking stage 2 with a front side surface or back side surface of the silicon wafer 1 facing upward. The silicon wafer 1 can be held by vacuum sucking on the vacuum sucking stage 2 connected to a vacuum source 4. Nevertheless, the silicon wafer can be held by other methods than the vacuum sucking.

The vacuum sucking stage 2 is capable of rotating in a θ direction in the drawing with the center of the vacuum sucking stage 2 serving as the rotation axis and with unillustrated rotation units, such as a θ axis motor and a θ spindle, located below the stage.

Next, description will be given of an example of the inventive method for etching a silicon wafer in which the etching apparatus 100 shown in FIG. 1 is used. Note that the silicon wafer to be etched according to the present invention is not particularly limited. The present invention is preferably applied for the treatment of PW because the decrease of etching speed on an impinging jet area in etching by conventional spin etching processing is more noticeable in the cases of PW and the like whose wafer top layers hardly have processing residual stress than in the cases of silicon wafers having ground surfaces with many processing residual stress.

The inventive method for etching a silicon wafer includes a spin etching step in which while the acid etching solution 8 stored in the etching-solution tank 6 is being supplied through the supply nozzle 3 to a front side surface or back side surface of a silicon wafer, the silicon wafer is rotated to expand a supply range of the acid etching solution to perform acid etching on the entire surface of the silicon wafer 1. Moreover, in the inventive method for etching a silicon wafer, a treatment described next is performed prior to this etching step.

Before the rotation of the silicon wafer is started in the spin etching step, the acid mixture 10 containing at least hydrofluoric acid and nitric acid is added dropwise within an impinging jet area 20. Thereby, the impinging jet area 20 is covered with the acid mixture 10. The impinging jet area 20 is located immediately below the supply nozzle 3. Within the impinging jet area 20, the acid etching solution 8 supplied from the supply nozzle 3 will impinge on the surface of the silicon wafer 1.

Herein, the impinging jet area 20 may be a circular region having a diameter 0.8 times or more and 1.6 times or less as large as an inner diameter of the supply nozzle 3. Specifically, for example, when the supply nozzle 3 has an inner diameter of 25 mm, the impinging jet area 20 can be a circular region having a diameter of 20 to 40 mm. Coating such an impinging jet area with the acid mixture can more effectively increase the etching speed on the impinging jet area. Note that the inner diameter of the supply nozzle 3 can be appropriately selected depending on the diameter of the silicon wafer to be etched, and so forth, and can be 10 to 50 mm, for example.

Here, the term impinging jet area refers a region where an acid etching solution jetted and supplied from the supply nozzle directly impinges on the surface of silicon wafer. This region may have a diameter equivalent to, larger than, or smaller than the inner diameter of the supply nozzle, depending on the shape of the jetting port of the supply nozzle, etc. To put it differently, the etching solution to be jetted can be supplied such that the diameter in the jetting direction forms uniformly straight flow, gradually expands, or gradually contracts.

Meanwhile, the acid mixture is preferably added dropwise in a liquid amount of 20 to 50 mL. Such an amount of the acid mixture 10 can cover only the inside of the impinging jet area 20 sufficiently and more reliably. This makes it possible to more effectively increase the etching speed on the impinging jet area 20 by the acid etching in the spin etching step.

Next, the spin etching step is performed. Within a period of 1 second or more and 2 seconds or less after the acid mixture is added dropwise within the impinging jet area 20, the rotation of the silicon wafer is preferably started to start the spin etching step of performing the acid etching. When a time of 1 second or more elapses before the rotation of the silicon wafer is started, this enables sufficient generation of nitrite ions autocatalytically generated from nitrogen oxide. When the time is 2 seconds or less, the productivity is not impaired, and it is possible to more effectively prevent surface roughness due to excessive reaction between the silicon and the acid mixture, and the like.

Next, an example of the spin etching step will be described in detail. When a predetermined number of rotations reaches after the rotation of the silicon wafer is started, the acid etching solution 8 is supplied from the etching-solution tank 6 to the supply nozzle 3 located above the vacuum sucking stage 2. The acid etching solution 8 is supplied onto the silicon wafer 1 being held and rotated on the vacuum sucking stage 2. As the silicon wafer 1 rotates, the acid etching solution 8 supplied on the silicon wafer 1 is moved on the silicon wafer 1 and discharged from the top of the wafer in the form of droplets 11 via an outer periphery of the silicon wafer 1. When the etching processing is ended after a predetermined etching margin is filled, the supply of the acid etching solution 8 from the etching-solution tank 6 is stopped, and the water 9 is supplied from the water supply source 7 to the supply nozzle 3. The water 9 is supplied onto the silicon wafer 1 being held and rotated on the vacuum sucking stage 2. As the silicon wafer 1 rotates, the water 9 supplied on the silicon wafer 1 is moved on the silicon wafer 1 and discharged as the droplets 11 from the outer periphery of the silicon wafer 1 while the acid etching solution 8 left on the silicon wafer 1 is replaced with the water 9. After the replacement of the acid etching solution 8 with water on the silicon wafer 1 is ended, the supply of the water 9 from the water supply source 7 is stopped, and the silicon wafer 1 is rotated at high speed to scatter all the water on the silicon wafer 1, so that dried silicon wafer 1 is obtained.

As the acid etching solution 8, a mixture solution containing hydrofluoric acid and nitric acid can be used. In this case, the mixing ratio in terms of mass % can be such that, for example, hydrofluoric acid ranges from 1 to 80%, and nitric acid ranges from 10 to 80%. Alternatively, it is also possible to use a mixture solution obtained by adding any one or more of acetic acid, phosphoric acid, and sulfuric acid to the mixture solution containing hydrofluoric acid and nitric acid in an appropriate combination. In this event, it is possible to mix acetic acid in a range of, for example, 10 to 30%, sulfuric acid in a range of, for example, 10 to 25%, and phosphoric acid in a range of, for example, 10 to 50% at any ratios therein. The use of such a mixture solution enables more efficient acid etching, and can further increase the etching speed in the impinging jet area.

Moreover, in the case where the above-described mixture solution is used as the acid etching solution 8, this acid etching solution 8 can also be used as the acid mixture that is added dropwise within the impinging jet area before the rotation of the silicon wafer is started. In this case, it is not necessary to separately provide supply systems for the acid mixture and for the acid etching solution, so that the apparatus is more simplified and more preferable.

The inventive etching method increases the overall etching speed in the impinging jet area immediately below the supply nozzle, making it possible to improve PV on the etching margin in the wafer plane. For example, in a case where an acid etching solution with Si dissolved in an amount of 20 g/L is used to spin-etch PW by a conventional method under such a condition that the targeted removal margin is 10 μm on average, the PV on the etching margin is normally about 2.1 μm. In contrast, the PV on the etching margin according to the etching by the inventive etching method is about 1.5 μm, and considerable improvement has been achieved.

### EXAMPLE

Hereinafter, the present invention will be specifically described with reference to Example. However, the present invention is not limited thereto.

### EXAMPLE

A silicon wafer was etched using a spin etching apparatus. The acid etching solution used was a mixture solution of hydrofluoric acid and nitric acid, and the mixing ratio in terms of mass % was such that hydrofluoric acid was 10% and nitric acid was 51%. This acid etching solution was also used as the acid mixture which was added dropwise within the impinging jet area. Note that the inner diameter of the supply nozzle was 25 mm. On the vacuum sucking stage in the etching apparatus, a PW having a diameter of 300 mm was placed as the silicon wafer and held by vacuum sucking. Before the rotation of the silicon wafer was started, 30 mL of the acid etching solution was added dropwise from supply nozzle, so that a region having a diameter of 30 mm immediately below the supply nozzle was covered with the acid etching solution. Two seconds after the addition dropwise, the rotation of the silicon wafer was started. When a predetermined number of rotations reached, the acid etching solution was supplied to perform spin etching, and the supply was switched to pure water to remove the acid etching solution. Further, supplying any chemical solution was stopped, and the silicon wafer was dried. The etching was performed such that the etching amount was 10 μm on average.

Note that, as described above, in acid etching of a silicon wafer by spin etching processing, the used acid etching solution is collected and used again as an acid etching solution. Hence, when a silicon wafer is etched with acid, the amount of Si dissolved and contained in the acid etching solution is increased in accordance with the number of wafers etched. Moreover, since this increase in the amount of Si dissolved means a decrease in etching chemical species contained in the acid etching solution, the increase in the amount of Si dissolved decreases the average etching speed. To evaluate the influence on TTV by such a change in the amount of Si dissolved also, multiple silicon wafers were etched as described above, except for varying the amount of Si dissolved in the acid etching solution.

The TTV evaluation of the etched silicon wafers was conducted with a flatness-profile measurement system SBW manufactured by KOBELCO Research Institute, Inc. The relation between the amount of Si dissolved in the acid etching solution in the etching and the TTV of the etched silicon wafer was examined.

### COMPARATIVE EXAMPLE

Silicon wafers were spin-etched and evaluated under the same conditions as in Example, except that no acid mixture (acid etching solution) was added dropwise before the rotation of any silicon wafer was started.

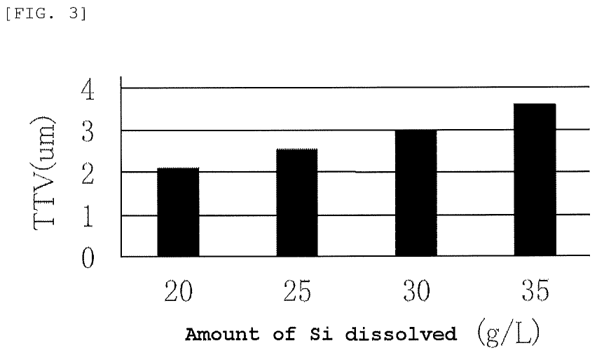

FIG. 2 shows the relation between the TTV after the etching by the etching method of Example and the amount of Si dissolved in the acid etching solution. It is revealed as can be seen from FIG. 2 that the larger the amount of Si dissolved in the acid etching solution, that is, the larger the number of silicon wafers treated with the acid etching solution (the longer the life), the larger the TTV.

FIG. 3 shows the relation between the TTV after the etching by the etching method of Comparative Example and the amount of Si dissolved in the acid etching solution. As can be seen from FIG. 3, the trend of the TTV that increased as the amount of Si dissolved in the acid etching solution was increased was the same as that in Example.

Meanwhile, the comparison among the data on the amount of Si dissolved which are equal between Example and Comparative Example in FIGS. 2, 3 reveals that the TTV after the etching in Example is smaller than that in Comparative Example by approximately 10% or more. It is revealed that Example of the present invention makes it possible to increase the overall etching speed in the impinging jet area immediately below the nozzle and improve the TTV after the etching when a silicon wafer is etched with acid by spin etch processing as above.

It should be noted that the present invention is not limited to the above-described embodiments. The embodiments are just examples, and any embodiments that substantially have the same feature and demonstrate the same functions and effects as those in the technical concept disclosed in claims of the present invention are included in the technical scope of the present invention.

1-5. (canceled)

6. A method for etching a silicon wafer, comprising a spin etching step in which while an acid etching solution is being supplied to a front side surface or back side surface of a silicon wafer through a supply nozzle, the silicon wafer is rotated to expand a supply range of the acid etching solution to perform acid etching throughout the front side surface or back side surface of the silicon wafer, wherein
before the rotation of the silicon wafer is started, an acid mixture containing at least hydrofluoric acid and nitric acid is added dropwise within an impinging jet area which is located immediately below the supply nozzle, and in which the acid etching solution supplied through the supply nozzle impinges on the surface of the silicon wafer, and
after the impinging jet area is covered with the acid mixture, the rotation of the silicon wafer is started to perform the spin etching step.

7. The method for etching a silicon wafer according to claim 6, wherein the impinging jet area is a circular region having a diameter 0.8 times or more and 1.6 times or less as large as an inner diameter of the supply nozzle.

8. The method for etching a silicon wafer according to claim 6, wherein before the rotation of the silicon wafer is started, the acid mixture is added dropwise in a liquid amount of 20 to 50 mL.

9. The method for etching a silicon wafer according to claim 7, wherein before the rotation of the silicon wafer is started, the acid mixture is added dropwise in a liquid amount of 20 to 50 mL.

10. The method for etching a silicon wafer according to claim 6, wherein within a period of 1 second or more and 2 seconds or less after the acid mixture is added dropwise within the impinging jet area, the rotation of the silicon wafer is started to perform the acid etching.

11. The method for etching a silicon wafer according to claim 7, wherein within a period of 1 second or more and 2 seconds or less after the acid mixture is added dropwise within the impinging jet area, the rotation of the silicon wafer is started to perform the acid etching.

12. The method for etching a silicon wafer according to claim 8, wherein within a period of 1 second or more and 2 seconds or less after the acid mixture is added dropwise within the impinging jet area, the rotation of the silicon wafer is started to perform the acid etching.

13. The method for etching a silicon wafer according to claim 9, wherein within a period of 1 second or more and 2 seconds or less after the acid mixture is added dropwise within the impinging jet area, the rotation of the silicon wafer is started to perform the acid etching.

14. The method for etching a silicon wafer according to claim 6, wherein the acid etching solution to be used is a mixture solution containing hydrofluoric acid and nitric acid, or the mixture solution further containing any one or more of acetic acid, phosphoric acid, and sulfuric acid.

15. The method for etching a silicon wafer according to claim 7, wherein the acid etching solution to be used is a mixture solution containing hydrofluoric acid and nitric acid, or the mixture solution further containing any one or more of acetic acid, phosphoric acid, and sulfuric acid.

16. The method for etching a silicon wafer according to claim 8, wherein the acid etching solution to be used is a mixture solution containing hydrofluoric acid and nitric acid, or the mixture solution further containing any one or more of acetic acid, phosphoric acid, and sulfuric acid.

17. The method for etching a silicon wafer according to claim 9, wherein the acid etching solution to be used is a mixture solution containing hydrofluoric acid and nitric acid, or the mixture solution further containing any one or more of acetic acid, phosphoric acid, and sulfuric acid.

18. The method for etching a silicon wafer according to claim 10, wherein the acid etching solution to be used is a mixture solution containing hydrofluoric acid and nitric acid, or the mixture solution further containing any one or more of acetic acid, phosphoric acid, and sulfuric acid.

19. The method for etching a silicon wafer according to claim 11, wherein the acid etching solution to be used is a mixture solution containing hydrofluoric acid and nitric acid, or the mixture solution further containing any one or more of acetic acid, phosphoric acid, and sulfuric acid.

20. The method for etching a silicon wafer according to claim 12, wherein the acid etching solution to be used is a mixture solution containing hydrofluoric acid and nitric acid, or the mixture solution further containing any one or more of acetic acid, phosphoric acid, and sulfuric acid.

21. The method for etching a silicon wafer according to claim 13, wherein the acid etching solution to be used is a mixture solution containing hydrofluoric acid and nitric acid, or the mixture solution further containing any one or more of acetic acid, phosphoric acid, and sulfuric acid.
